(19) United States
(12) Patent Application Publication
(10) Pub. No.: US 2026/0121601 A1
(43) Pub. Date: Apr. 30, 2026

(54) AMPLIFIER AND OSCILLOSCOPE

(71) Applicant: R IGOL TECHNOLOGIES CO., LTD., Jiangsu (CN)

(72) Inventors: Bo YAN, Jiangsu (CN); Jianwei LI, Jiangsu (CN); Yue WANG, Jiangsu (CN)

(21) Appl. No.: 19/116,828

(22) PCT Filed: Oct. 16, 2024
(86) PCT No.: PCT/CN2024/125103

§ 371 Date: Mar. 28, 2025

(30) Foreign Application Priority Data
Feb. 23, 2024 (CN) 202410199737.4

(51) Int. Cl. H03F 3/45; G01R 1/30; G01R 13/00

(52) U.S. Cl. CPC H03F 3/45475; G01R 1/30; G01R 13/00; H03F 2200/261; H03F 2203/45114; H03F 2203/45138; H03F 2203/45242

(57) ABSTRACT

An amplifier includes a transconductance amplification module, a feedforward transconductance module, and a gain control module. An input control terminal pair of the transconductance amplification module is connected to an input signal pair, and the transconductance amplification module is configured to convert the input signal pair into an output current pair and output the output current pair. A first feedforward control terminal pair included in the feedforward transconductance module is connected to the input signal pair and outputs a feedforward current pair. The gain control module includes a first differential pair and a second differential pair. The first differential pair is configured to perform compensations for a positive-phase output current and a negative-phase output current of the output current pair respectively. The second differential pair is configured to perform compensations for the positive-phase output current and the negative-phase output current in the output current pair respectively.

### CROSS-REFERENCE TO RELATED APPLICATIONS

This application is a national stage application filed under 37 U.S.C. 371 based on International Patent Application No. PCT/CN2024/125103, filed Oct. 16, 2024, which claims priority to Chinese Patent Application No. 202410199737.4 filed with the China National Intellectual Property Administration (CNIPA) on Feb. 23, 2024, the disclosures of which are incorporated herein by reference in their entireties.

### TECHNICAL FIELD

The present application relates to the field of circuit technology, for example, to an amplifier and an oscilloscope.

### BACKGROUND

High-bandwidth amplifiers are often used in systems that need to process high-frequency signals, such as oscilloscope analog front-ends and probe analog front-ends. In these circuits, the high-bandwidth amplifiers enable high-frequency signals to maintain high gains and frequency responses. The high-frequency responses of high-bandwidth amplifiers in the related art are greatly affected by chip processes and printed circuit board processes. This process deviation may cause inconsistent frequency responses of amplifiers from different batches, which does not meet user requirements.

### SUMMARY

The present application provides an amplifier and an oscilloscope to eliminate a process deviation.

The present application provides an amplifier. The amplifier includes a transconductance amplification module, a feedforward transconductance module, and a gain control module.

The transconductance amplification module includes an input control terminal pair, where the input control terminal pair is connected to an input signal pair, the transconductance amplification module is configured to convert the input signal pair into an output current pair and output the output current pair.

The feedforward transconductance module includes a first feedforward control terminal pair, where the first feedforward control terminal pair is connected to the input signal pair and outputs a feedforward current pair, and the feedforward current pair includes a positive-phase feedforward current and a negative-phase feedforward current.

The gain control module includes a first differential pair and a second differential pair, where an input terminal of the first differential pair and an input terminal of the second differential pair serve as a feedforward current input terminal pair of the gain control module, the input terminal of the first differential pair is connected to the positive-phase feedforward current, a first output terminal of the first differential pair outputs a first positive-phase compensation current which is configured to compensate for a negative-phase output current in the output current pair, and a second output terminal of the first differential pair outputs a second positive-phase compensation current to compensate for a positive-phase output current of the output current pair; the input terminal of the second differential pair is connected to the negative-phase feedforward current, a first output terminal of the second differential pair outputs a first negative-phase compensation current to compensate for the negative-phase output current of the output current pair, and a second output terminal of the second differential pair outputs a second negative-phase compensation current to compensate for the positive-phase output current of the output current pair.

The present application further provides an oscilloscope. The oscilloscope includes a front-end module, a sampling module, an input module, a control processing module, a display module, and a storage module, where the front-end module includes an attenuation unit and the amplifier provided in any embodiment of the present application, where an input terminal of the amplifier is connected to the attenuation unit.

The present application further provides an oscilloscope probe. The oscilloscope probe includes a probe input terminal, a probe input resistor, a probe input capacitor, the amplifier provided in any embodiment of the present application, and a probe output terminal, where an input terminal of the amplifier is connected to the probe input resistor and the probe input capacitor separately.

### BRIEF DESCRIPTION OF DRAWINGS

FIG. 1 is a diagram illustrating the structure of an amplifier according to an embodiment of the present application.

FIG. 2 is another diagram illustrating the circuit of an amplifier according to an embodiment of the present application.

FIG. 3 is another diagram illustrating the circuit of an amplifier according to an embodiment of the present application.

FIG. 4 is another diagram illustrating the circuit of an amplifier according to an embodiment of the present application.

FIG. 5 is another diagram illustrating the circuit of an amplifier according to an embodiment of the present application.

FIG. 6 is another diagram illustrating the circuit of an amplifier according to an embodiment of the present application.

FIG. 7 is another diagram illustrating the circuit of an amplifier according to an embodiment of the present application.

FIG. 8 is another diagram illustrating the circuit of an amplifier according to an embodiment of the present application.

FIG. 9 is another diagram illustrating the circuit of an amplifier according to an embodiment of the present application.

FIG. 10 is another diagram illustrating the circuit of an amplifier according to an embodiment of the present application.

FIG. 11 is another diagram illustrating the circuit of an amplifier according to an embodiment of the present application.

FIG. 12 is another diagram illustrating the circuit of an amplifier according to an embodiment of the present application.

FIG. 13 is another diagram illustrating the circuit of an amplifier according to an embodiment of the present application.

FIG. 14 is a diagram illustrating the structure of an oscilloscope according to an embodiment of the present application.

FIG. 15 is another diagram illustrating the structure of an oscilloscope according to an embodiment of the present application.

### DETAILED DESCRIPTION

It is to be noted that the terms such as “first” and “second” in the description, claims, and drawings of the present application are used for distinguishing between similar objects and are not necessarily used for describing a particular order or sequence. It is to be understood that data used in this manner are interchangeable where appropriate so that embodiments of the present application described herein can be implemented in an order not illustrated or described herein. In addition, the terms “comprising”, “including”, or any other variations thereof herein are intended to encompass a non-exclusive inclusion. For example, a process, method, system, product, or device that includes a series of steps or units not only includes the expressly listed steps or units but may also include other steps or units that are not expressly listed or are inherent to such process, method, product, or device.

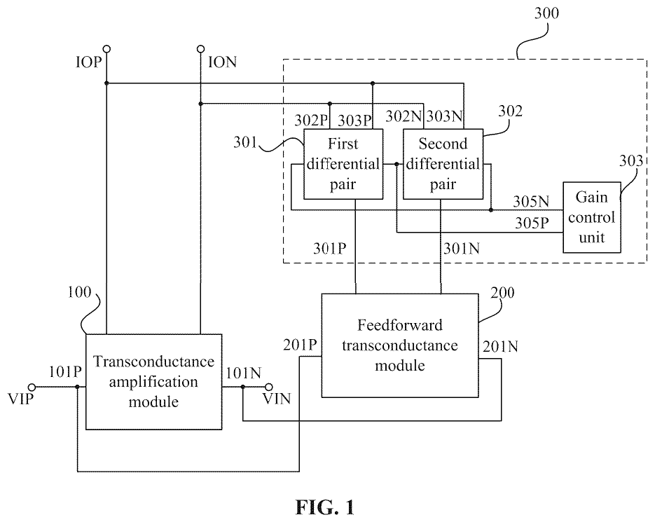

FIG. 1 is a diagram illustrating the structure of an amplifier according to an embodiment of the present application. Referring to FIG. 1, the amplifier includes a transconductance amplification module 100, a feedforward transconductance module 200, and a gain control module 300.

The transconductance amplification module 100 includes an input control terminal pair, and the input control terminal pair (including a terminal 101P and a terminal 101N) is connected to an input signal pair (including a positive-phase input signal VIP and a negative-phase input signal VIN). The transconductance amplification module 100 is configured to convert the input signal pair (including the positive-phase input signal VIP and the negative-phase input signal VIN) into an output current pair (including a positive-phase output current IOP and a negative-phase output current ION) and output the output current pair.

The feedforward transconductance module 200 includes a first feedforward control terminal pair (including a terminal 201P and a terminal 201N), and the first feedforward control terminal pair (including the terminal 201P and the terminal 201N) is connected to the input signal pair (including the positive-phase input signal VIP and the negative-phase input signal VIN). The feedforward transconductance module 200 is configured to generate a feedforward current pair (including a positive-phase feedforward current and a negative-phase feedforward current) according to the input signal pair.

The gain control module 300 includes a first differential pair 301 and a second differential pair 302. An input terminal of the first differential pair 301 and an input terminal of the second differential pair 302 serve as a feedforward current input terminal pair (including a terminal 301P and a terminal 301N) of the gain control module. The input terminal of the first differential pair 301 is connected to the positive-phase feedforward current, a first output terminal 302P of the first differential pair 301 outputs a first positive-phase compensation current to compensate for the negative-phase output current of the output current pair, and a second output terminal 303P of the first differential pair 301 outputs a second positive-phase compensation current to compensate for the positive-phase output current of the output current pair. The input terminal of the second differential pair 302 is connected to the negative-phase feedforward current, a first output terminal 302N of the second differential pair 302 outputs a first negative-phase compensation current to compensate for the negative-phase output current of the output current pair, and a second output terminal 303N of the second differential pair 302 outputs a second negative-phase compensation current to compensate for the positive-phase output current of the output current pair.

The feedforward current input terminal pair (including the terminal 301P and the terminal 301N) is connected to the feedforward current pair generated by the feedforward transconductance module 200. The currents output by the first output terminal 302P of the first differential pair 301 and the second output terminal 303P of the first differential pair 301 are the positive-phase compensation currents generated according to the positive-phase input signal VIP, and the positive-phase compensation currents are not only used for performing compensation for the positive-phase output current IOP but also used for performing compensation for the negative-phase output current ION. Similarly, the currents output by the first output terminal 302N of the second differential pair 302 and the second output terminal 303N of the second differential pair 302 are the negative-phase compensation currents generated according to the negative-phase input signal VIN. The negative-phase compensation currents are not only used for performing compensation for the negative-phase output current ION but also used for performing compensation for the positive-phase output current IOP.

In other words, the current output by the second output terminal 303P of the first differential pair 301 is the positive-phase compensation current generated according to the positive-phase input signal VIP, and the current output by the first output terminal 302N of the second differential pair 302 is the negative-phase compensation current generated according to the negative-phase input signal VIN. The second output terminal 303P of the first differential pair 301 corresponds to the positive-phase output current IOP, and the first output terminal 302N of the second differential pair 302 corresponds to the negative-phase output current ION. That is, the positive-phase compensation current compensates for the positive-phase output current IOP of the transconductance amplification module 100, and the negative-phase compensation current compensates for the negative-phase output current ION of the transconductance amplification module 100 at the same time. It is to be defined that the compensation current output by the second output terminal 303P of the first differential pair 301 and the compensation current output by the first output terminal 302N of the second differential pair 302 form a first compensation current pair, and the compensation current pair is superimposed with the output current pair in a corresponding manner and output.

The current output by the first output terminal 302P of the first differential pair 301 is the positive-phase compensation current generated according to the positive-phase input signal VIP, and the current output by the second output terminal 303N of the second differential pair 302 is the negative-phase compensation current generated according to the negative-phase input signal VIN. The first output terminal 302P of the first differential pair 301 corresponds to the negative-phase output current ION, and the second output terminal 303N of the second differential pair 302 corresponds to the positive-phase output current IOP. That is, the positive-phase compensation current compensates for the negative-phase output current ION of the transconductance amplification module 100, and the negative-phase compensation current compensates for the positive-phase output current IOP of the transconductance amplification module 100 at the same time. It is to be defined that the compensation currents output by the first output terminal 302P of the first differential pair 301 and the second output terminal 303N of the second differential pair 302 form a second compensation current pair, and the compensation current pair is superimposed with the output current pair in a staggered manner and output.

Exemplarily, the operation principle of the amplifier is as follows: the input signal pair (including the positive-phase input signal VIP and the negative-phase input signal VIN) is converted into the output current pair (including the positive-phase output current IOP and the negative-phase output current ION) through the transconductance amplification module 100. The feedforward transconductance module 200 generates the feedforward current pair according to the input signal pair (including the positive-phase input signal VIP and the negative-phase input signal VIN). The gain control module 300 generates the two compensation current pairs according to the feedforward current pair. One of the two compensation current pairs is superimposed on an output terminal of the amplifier in a corresponding manner, and the other one of the two compensation current pairs is superimposed on the output terminal of the amplifier in a staggered manner, thereby performing compensation on the frequency responses of the original output currents. The frequencies and gains of the two compensation current pairs are controlled by the gain control module 300 so that according to the frequency response characteristics of amplifiers from different batches, the frequencies and gains can be pulled down when the frequency response is high and can be pulled up when the frequency response is low until the frequencies and gains can be leveled.

In conclusion, in the technical solutions of this embodiment, the transconductance amplification module 100 converts the input signal pair (including the positive-phase input signal VIP and the negative-phase input signal VIN) into the output current pair (including the positive-phase output current IOP and the negative-phase output current ION), the gain control module 300 generates the two compensation current pairs according to the input signal pair (including the positive-phase input signal VIP and the negative-phase input signal VIN) at the same time, and the two compensation current pairs are superimposed and output with the output current pair in a corresponding manner and a staggered manner respectively so that the influence of a process deviation on the frequency response can be eliminated.

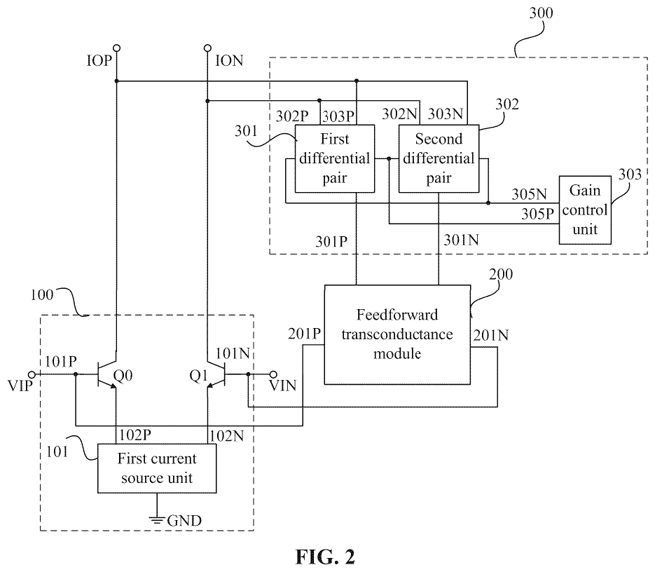

FIG. 2 is another diagram illustrating the circuit of an amplifier according to an embodiment of the present application. Referring to FIG. 2, the transconductance amplification module 100 includes a first current source unit 101, a zeroth transistor Q0, and a first transistor Q1. The first current source unit 101 includes a first connection point pair. The first connection point pair includes a first connection point 102P and a second connection point 102N. The first current source unit 101 is electrically connected to a first power supply voltage (for example, a grounding voltage GND).

A control terminal of the zeroth transistor Q0 and a control terminal of the first transistor Q1 serve as the input control terminal pair (including the terminal 101P and the terminal 101N) of the transconductance amplification module 100. A first terminal of the zeroth transistor Q0 is electrically connected to the first connection point 102P of the first current source unit 101, and a first terminal of the first transistor Q1 is electrically connected to the second connection point 102N of the first current source unit 101. A second terminal of the zeroth transistor Q0 and a second terminal of the first transistor Q1 output the output current pair (including the positive-phase output current IOP and the negative-phase output current ION) of the transconductance amplification module 100.

Exemplarily, the operation principle of the transconductance amplification module 100 is as follows: the positive-phase input signal VIP is converted into the positive-phase output current IOP through the zeroth transistor Q0, and the negative-phase input signal VIN is converted into the negative-phase output current ION through the first transistor Q1. The gain of the output current pair is controlled by the first current source unit 101.

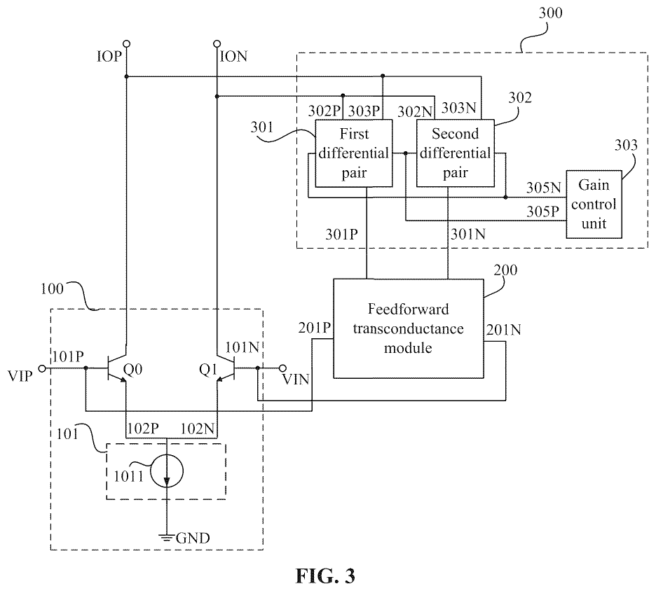

FIG. 3 is another diagram illustrating the circuit of an amplifier according to an embodiment of the present application. Referring to FIG. 3, in an embodiment, the first current source unit 101 includes a first current source 1011. A current input terminal of the first current source 1011 is electrically connected to the first connection point 102P of the first current source unit 101 and the second connection point 102N of the first current source unit 101, and a current output terminal of the first current source 1011 is electrically connected to the first power supply voltage.

A current of the first current source 1011 is controlled so that the transconductance of the transistors in the transconductance amplification module 100 can be controlled, thereby controlling the gains of the output currents. This arrangement is easy to implement, does not increase the circuit area, and is conducive to controlling the cost.

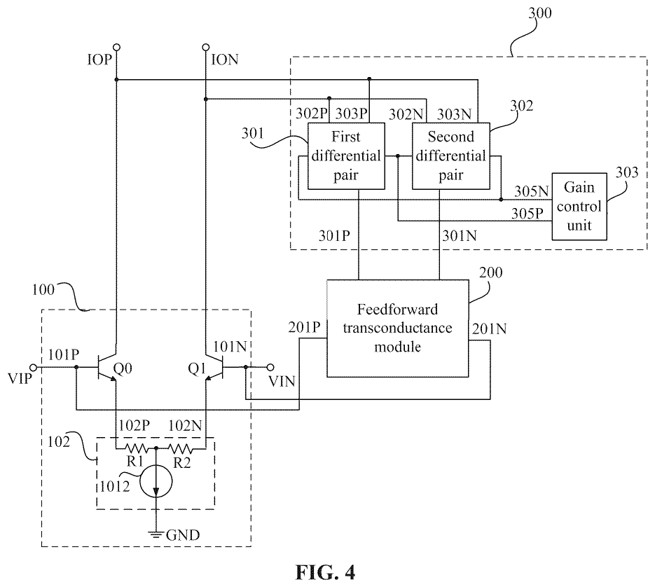

FIG. 4 is another diagram illustrating the circuit of an amplifier according to an embodiment of the present application. Referring to FIG. 4, in another embodiment, the first current source unit 102 includes a second current source 1012, a first resistor unit R1, and a second resistor unit R2. The first resistor unit R1 is connected in series between a current input terminal of the second current source 1012 and the first connection point 102P of the first current source unit 101. The second resistor unit R2 is connected in series between the current input terminal of the second current source 1012 and the second connection point 102N of the first current source unit 101. A current output terminal of the second current source 1012 is electrically connected to the first power supply voltage.

A current of the second current source 1012, the resistance of the first resistor unit R1, and the resistance of the second resistor unit R2 are controlled so that the equivalent transconductance of the transconductance amplification module 100 can be controlled, thereby controlling the gains of the output currents of the transconductance amplification module 100. Compared with the arrangement of a single current source, this arrangement adds resistor units to emitters of the transistors in the transconductance amplification module 100 so that the gains of the output currents can be jointly controlled by the currents of the current source and the resistances of the resistor units, thereby increasing the adjustability of the gains of the output currents.

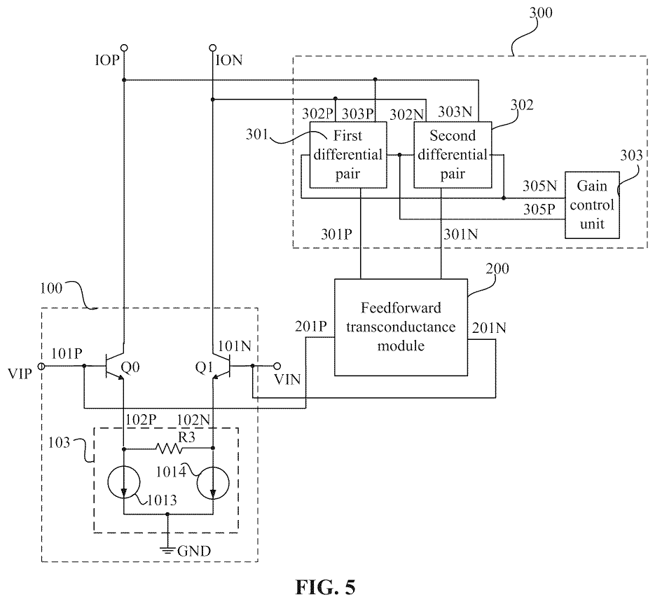

FIG. 5 is another diagram illustrating the circuit of an amplifier according to an embodiment of the present application. Referring to FIG. 5, in another embodiment, the first current source unit 103 includes a third current source 1013, a fourth current source 1014, and a third resistor unit R3. A current input terminal of the third current source 1013 is electrically connected to the first connection point 102P of the first current source unit 101, and a current input terminal of the fourth current source 1014 is electrically connected to the second connection point 102N of the first current source unit 101. The third resistor unit R3 is further connected between the current input terminal of the third current source 1013 and the current input terminal of the fourth current source 1014. A current output terminal of the third current source 1013 and a current output terminal of the fourth current source 1014 are both electrically connected to the first power supply voltage.

A current of the third current source 1013, a current of the fourth current source 1014, and the resistance of the third resistor unit R3 are controlled so that the equivalent transconductance of the transconductance amplification module 100 can be controlled, thereby controlling the gains of the output currents. Compared with the structure in which a single current source is connected to two resistor units, this arrangement provides a single resistor unit without considering the problem of resistor matching, which is conducive to stable adjustment of the gains of the output currents.

With continued reference to FIGS. 1 to 5, the gain control module 300 further includes a gain control unit 303. The gain control unit 303 includes a second connection point pair (including a connection point 305P and a connection point 305N). The second connection point pair (including the connection point 305P and the connection point 305N) of the gain control unit 303 is electrically connected to control terminals of the first differential pair 301, and the second connection point pair (including the connection point 305P and the connection point 305N) is electrically connected to control terminals of the second differential pair 302. The second connection point pair (including the connection point 305P and the connection point 305N) of the gain control unit 303 outputs a second control current pair for gain control of the output currents of the first differential pair 301 and the second differential pair 302.

In this embodiment, the first differential pair 301, by setting the second differential pair 302, and the gain control unit 303, the frequencies and gains of output currents of the feedforward transconductance module 200 are controlled, which is conducive to the further elimination of the process deviation and compensation for the frequency response.

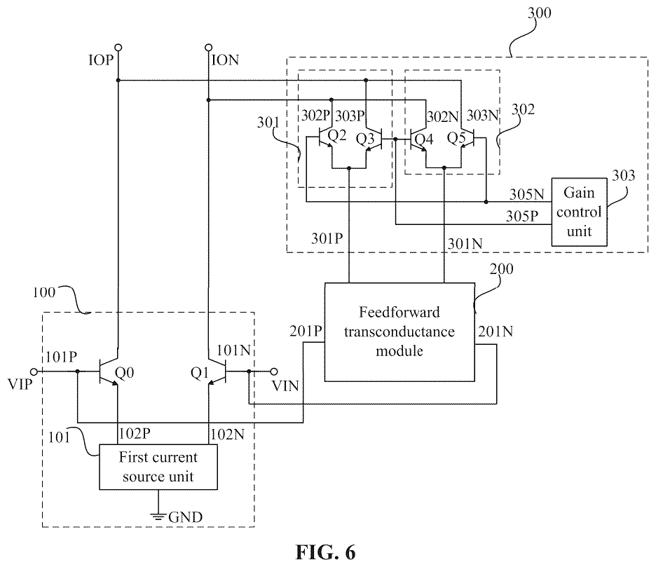

FIG. 6 is another diagram illustrating the circuit of an amplifier according to an embodiment of the present application. Referring to FIG. 6, the first differential pair 301 includes a second transistor Q2 and a third transistor Q3. A first terminal of the second transistor Q2 and a first terminal of the third transistor Q3 are electrically connected and serve as the input terminal (that is, the terminal 301P) of the first differential pair 301. A control terminal of the second transistor Q2 and a control terminal of the fifth transistor Q5 are electrically connected. The control terminal of the second transistor Q2 and a control terminal of the third transistor serve as a control terminal pair of the first differential pair 301. A second terminal of the second transistor Q2 serves as the first output terminal 302P of the first differential pair 301 and outputs the first positive-phase compensation current. A second terminal of the third transistor Q3 serves as the second output terminal 303P of the first differential pair 301 and outputs the second positive-phase compensation current.

With continued reference to FIG. 6, the second differential pair 302 includes a fourth transistor Q4 and a fifth transistor Q5. A first terminal of the fourth transistor Q4 and a first terminal of the fifth transistor Q5 are electrically connected and serve as the input terminal (the terminal 301N) of the second differential pair 302. A control terminal of the third transistor Q3 and a control terminal of the fourth transistor Q4 are electrically connected. The control terminal of the fourth transistor Q4 and the control terminal of the fifth transistor Q5 serve as a control terminal pair of the second differential pair 302. A second terminal of the fourth transistor Q4 serves as the first output terminal 302N of the second differential pair 302 and outputs the first negative-phase compensation current. A second terminal of the fifth transistor Q5 serves as the second output terminal 303N of the second differential pair 302 and outputs the second negative-phase compensation current.

The second output terminal 303P of the first differential pair 301 and the second output terminal 303N of the second differential pair 302 output the second compensation current pair, and the first output terminal 302P of the first differential pair 301 and the first output terminal 302N of the second differential pair 302 output the first compensation current pair.

Exemplarily, the operation principle of the first differential pair 301 and the second differential pair 302 is as follows: the positive-phase compensation current generates the first positive-phase compensation current after passing through the second transistor Q2 and simultaneously generates the second positive-phase compensation current after passing through the third transistor Q3. The negative-phase compensation current generates the first negative-phase compensation current after passing through the fourth transistor Q4 and simultaneously generates the second negative-phase compensation current after passing through the fifth transistor Q5. The second positive-phase compensation current and the first negative-phase compensation current form the first compensation current pair, and the first positive-phase compensation current and the second negative-phase compensation current form the second compensation current pair.

In this embodiment, the second transistor Q2 and the third transistor Q3 are disposed in the first differential pair 301, and the fourth transistor Q4 and the fifth transistor Q5 are disposed in the second differential pair 302 so that the first compensation current pair and the second compensation current pair are generated according to the input signals and superimposed on the output current pair, thereby being conducive to the further elimination of the process deviations and compensation on the frequency response.

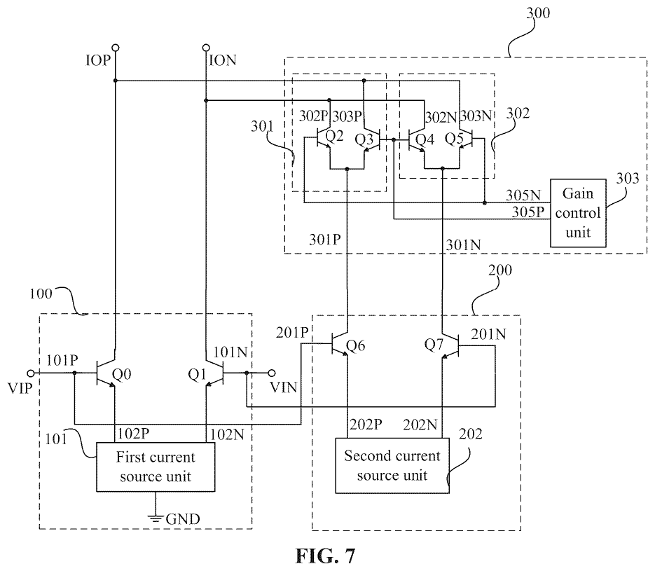

FIG. 7 is another diagram illustrating the circuit of an amplifier according to an embodiment of the present application. Referring to FIG. 7, the feedforward transconductance module 200 includes a sixth transistor Q6, a seventh transistor Q7, and a second current source unit 202. The second current source unit 202 includes a third connection point pair (including a connection point 202P and a connection point 202N).

A control terminal of the sixth transistor Q6 and a control terminal of the seventh transistor Q7 serve as the first feedforward control terminal pair (including the terminal 201P and the terminal 201N) of the feedforward transconductance module 200. A first terminal of the sixth transistor Q6 and a first terminal of the seventh transistor Q7 are electrically connected to the third connection point pair (including the third connection point 202P and the fourth connection point 202N) of the second current source unit 202. A second terminal of the sixth transistor Q6 and a second terminal of the seventh transistor Q7 are electrically connected to the feedforward current input terminal pair (including the terminal 301P and the terminal 301N) of the gain control module 300 separately. Exemplarily, the second terminal of the sixth transistor Q6 is electrically connected to the first terminal of the second transistor Q2 and the first terminal of the third transistor Q3; the second terminal of the seventh transistor Q7 is electrically connected to the first terminal of the fourth transistor Q4 and the first terminal of the fifth transistor Q5.

The third connection point pair (including the connection point 202P and the connection point 202N) of the second current source unit 202 outputs a first control current pair to perform frequency control on the output currents of the feedforward transconductance module 200.

Exemplarily, the operation principle of the feedforward transconductance module 200 is as follows: under the control of the second current source unit 202, the positive-phase input signal VIP is converted into a positive-phase compensation current through the sixth transistor Q6, and the negative-phase input signal VIN is converted into a negative-phase compensation current through the seventh transistor Q7.

The positive-phase compensation current generates the first positive-phase compensation current after passing through the second transistor Q2 and simultaneously generates the second positive-phase compensation current after passing through the third transistor Q3. The negative-phase compensation current generates the first negative-phase compensation current after passing through the fourth transistor Q4 and simultaneously generates the second negative-phase compensation current after passing through the fifth transistor Q5. The second positive-phase compensation current and the first negative-phase compensation current form the first compensation current pair, and the first positive-phase compensation current and the second negative-phase compensation current form the second compensation current pair.

It can be seen that the feedforward transconductance module 200 generates currents related to the frequencies of the output currents of the feedforward transconductance module 200 through the second current source unit 202, that is, the first control current pair, to control the frequencies of the output currents of the feedforward transconductance module 200. The gain control module 300 generates currents related to the gains of the output currents of the feedforward transconductance module 200, that is, the second control current pair, to control the gains of the output currents of the feedforward transconductance module 200.

In this embodiment, the sixth transistor Q6, the seventh transistor Q7, and the second current source unit 202 are disposed in the feedforward transconductance module 200 so that the frequency-controllable positive-phase compensation current and the frequency-controllable negative-phase compensation current can be generated according to the input signals and can be further superimposed on the output current pair through the gain control module 300, thereby being conducive to the further elimination of the process deviations and compensation on the frequency response.

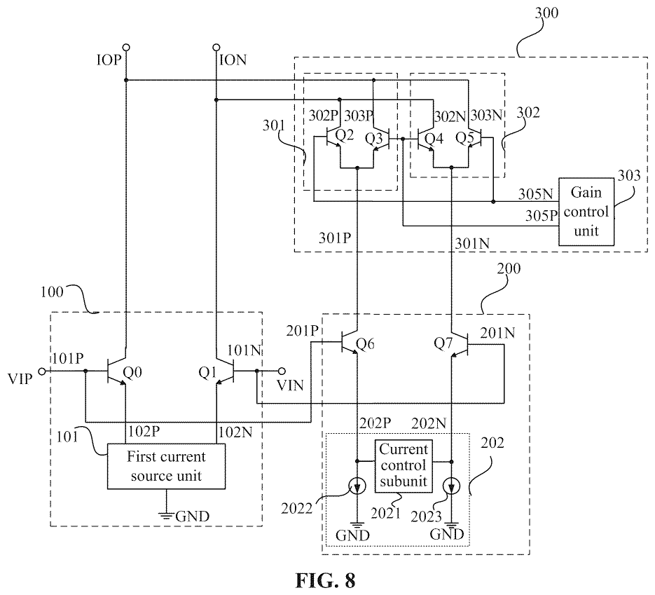

FIG. 8 is another diagram illustrating the circuit of an amplifier according to an embodiment of the present application. Referring to FIG. 8, the third connection point pair of the second current source unit 202 includes the third connection point 202P and the fourth connection point 202N. The second current source unit 202 includes a fifth current source 2022, a sixth current source 2023, and a current control subunit 2021.

A current input terminal of the fifth current source 2022 serves as the third connection point 202P of the second current source unit 202, and a current output terminal of the fifth current source 2022 is electrically connected to a fifth power supply voltage (for example, a grounding voltage GND).

A current input terminal of the sixth current source 2023 serves as the fourth connection point 202N of the second current source unit 202, and a current output terminal of the sixth current source 2023 is electrically connected to a sixth power supply voltage (for example, a grounding voltage GND).

The current control subunit 2021 is connected in series between the current input terminal of the fifth current source 2022 and the current input terminal of the sixth current source 2023.

A current of the fifth current source 2022 and a current of the sixth current source 2023 are controlled so that the transconductance of the sixth transistor Q6 and the transconductance of the seventh transistor Q7 can be controlled, thereby controlling the gains of output currents, and controlling the frequencies of the output currents through the current control subunit 2021. This arrangement has a simple circuit structure and is easy to implement.

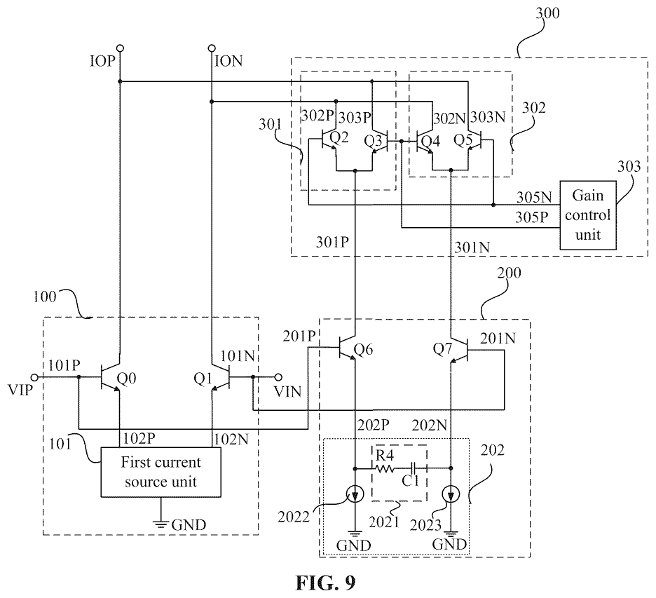

FIG. 9 is another diagram illustrating the circuit of an amplifier according to an embodiment of the present application. Referring to FIG. 9, in an embodiment, the current control subunit 2021 includes a fourth resistor unit R4 and a first capacitor unit C1. A first terminal of the fourth resistor unit R4 serves as a first terminal of the current control subunit 2021, a second terminal of the fourth resistor unit R4 is electrically connected to a first terminal of the first capacitor unit C1, and a second terminal of the first capacitor unit C1 serves as a second terminal of the current control subunit 2021.

A frequency-related current is generated on the fourth resistor unit R4 and the first capacitor unit C1, so the frequency and gain of a compensation current are determined by the resistance of the fourth resistor unit R4 and the capacitance of the first capacitor unit C1. This arrangement has a simple circuit structure and is easy to implement.

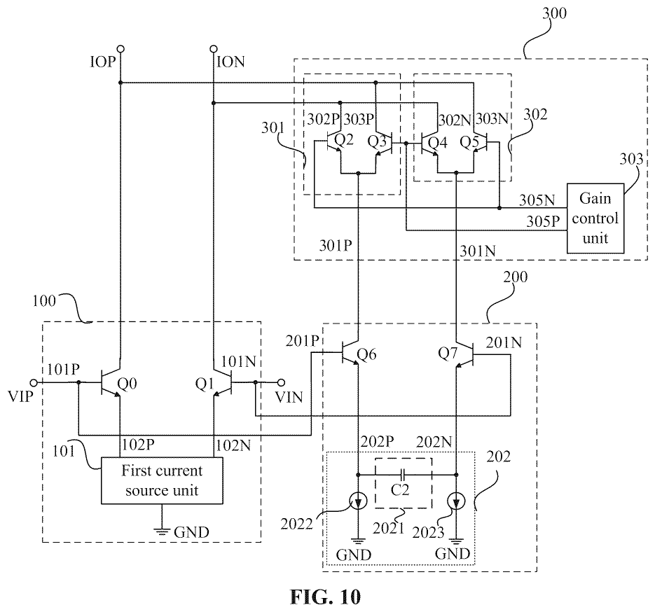

FIG. 10 is another diagram illustrating the circuit of an amplifier according to an embodiment of the present application. Referring to FIG. 10, in another embodiment, the current control subunit 2021 includes a second capacitor unit C2. A first terminal of the second capacitor unit C2 serves as the first terminal of the current control subunit 2021, and a second terminal of the second capacitor unit C2 serves as the second terminal of the current control subunit 2021.

A frequency-related current is generated at the two terminals of the second capacitor unit C2, and the frequency and gain of a compensation current are determined by the capacitance of the second capacitor unit C2. This arrangement is suitable for a circuit that performs compensation on a high-frequency current. Compared with the form of a resistor and a capacitor that are connected in series, this arrangement saves the circuit area and is conducive to reducing costs.

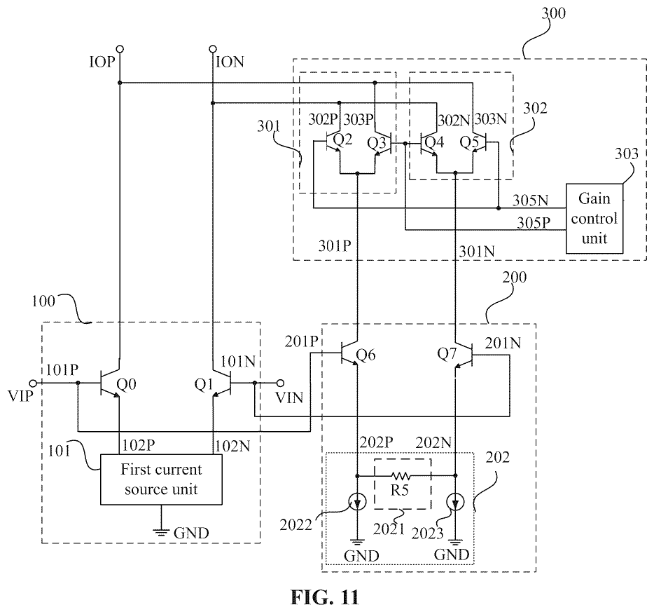

FIG. 11 is another diagram illustrating the circuit of an amplifier according to an embodiment of the present application. Referring to FIG. 11, in another embodiment, the current control subunit 2021 includes a fifth resistor unit R5. A first terminal of the fifth resistor unit R5 serves as the first terminal of the current control subunit 2021, and a second terminal of the fifth resistor unit R5 serves as the second terminal of the current control subunit 2021.

A frequency-related current is generated on the fifth resistor unit R5, and the gain of a compensation current is determined by the resistance of the fifth resistor unit R5. With this configuration, the frequency of the compensation current is in a full frequency band, that is, the compensation current can perform compensation on both a direct current signal and alternating current signals of different frequencies, which is conducive to the further elimination of the process deviations and compensation on the frequency response.

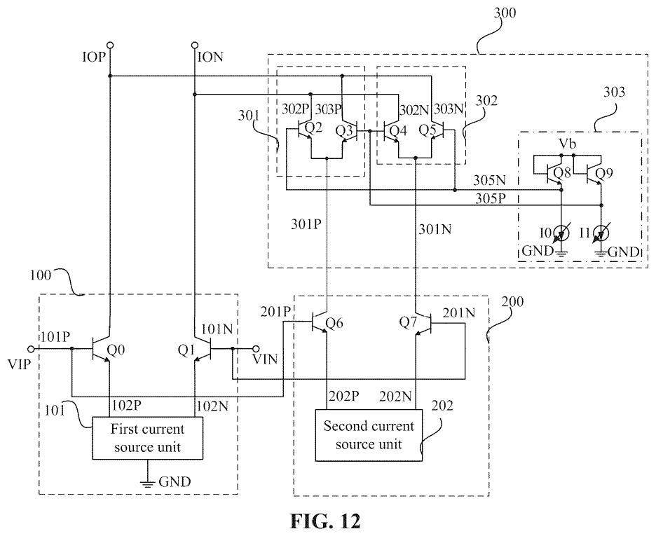

FIG. 12 is another diagram illustrating the circuit of an amplifier according to an embodiment of the present application. Referring to FIG. 12, the gain control unit 303 further includes a first adjustable current source I0, a second adjustable current source I1, an eighth transistor Q8, and a ninth transistor Q9.

A first terminal of the eighth transistor Q8 and a first terminal of the ninth transistor Q9 are electrically connected to a current input terminal of the first adjustable current source I0 and a current input terminal of the second adjustable current source I1 respectively, and a control terminal of the eighth transistor Q8, a control terminal of the ninth transistor Q9, a second terminal of the eighth transistor Q8, and a second terminal of the ninth transistor Q9 are electrically connected to a second power supply voltage Vb separately.

The current input terminal of the first adjustable current source I0 and the current input terminal of the second adjustable current source I1 serve as the second connection point pair (including the connection point 305P and the connection point 305N) of the gain control unit 303. A current output terminal of the first adjustable current source I0 is electrically connected to a third power supply voltage (for example, a grounding voltage GND). A current output terminal of the second adjustable current source I1 is electrically connected to a fourth power supply voltage (for example, a grounding voltage GND).

Exemplarily, using a transistor being a triode as an example, a control terminal of the transistor is a base of the triode, a first terminal of the transistor is an emitter of the triode, and a second terminal of the transistor is a collector of the triode. The operation principle of the gain control unit 303 is as follows: voltages of the bases of the second transistor Q2, the third transistor Q3, the fourth transistor Q4, and the fifth transistor Q5 are controlled so that the gains of the output currents of the first differential pair and the second differential pair are controlled. When the voltages of the bases of the second transistor Q2, the third transistor Q3, the fourth transistor Q4, and the fifth transistor Q5 are equal, the first positive-phase compensation current output by the second transistor Q2 flows to a negative-phase output terminal, the second positive-phase compensation current output by the third transistor Q3 flows to an in-phase output terminal, the first negative-phase compensation current output by the fourth transistor Q4 flows to a negative-phase output terminal, and the second negative-phase compensation current output by the fifth transistor Q5 flows to an in-phase output terminal. In this case, the compensation currents flowing to the in-phase output terminals and the negative-phase output terminals offset each other and do not affect the gains of the output currents.

When the gain control unit 303 is adjusted to increase a current of the first adjustable current source I0 and decrease a current of the second adjustable current source I1, a voltage of the emitter of the eighth transistor Q8 is decreased, and a voltage of the emitter of the ninth transistor Q9 is increased. Thus, the voltages of the bases of the third transistor Q3 and the fourth transistor Q4 are controlled to increase, the second positive-phase compensation current flowing to the in-phase output terminal is increased, and the first negative-phase compensation current flowing to the negative-phase output terminal is increased. The voltages of the bases of the second transistor Q2 and the fifth transistor Q5 are decreased, the second negative-phase compensation current flowing to the in-phase output terminal is decreased, and the first positive-phase compensation current flowing to the negative-phase output terminal is decreased. Ultimately, effective currents flowing to the in-phase output terminals and the negative-phase output terminals are increased, and the overall current gain is increased. Exemplarily, when the frequency response of a frequency point is low, the gain of a compensation current is required to increase so that compensation is performed on the frequency response.

When the gain control unit 303 is adjusted to decrease the current of the first adjustable current source I0 and increase the current of the second adjustable current source I1, the voltage of the emitter of the eighth transistor Q8 is increased, and the voltage of the emitter of the ninth transistor Q9 is decreased. Thus, the voltages of the bases of the third transistor Q3 and the fourth transistor Q4 are controlled to decrease, the second positive-phase compensation current flowing to the in-phase output terminal is decreased, and the first negative-phase compensation current flowing to the negative-phase output terminal is decreased. The voltages of the bases of the second transistor Q2 and the fifth transistor Q5 are increased, the second negative-phase compensation current flowing to the in-phase output terminal is increased, and the first positive-phase compensation current flowing to the negative-phase output terminal is increased. Ultimately, the effective currents flowing to the in-phase output terminals and the negative-phase output terminals are decreased, and the overall current gain is decreased. Exemplarily, when the frequency response of the frequency point is high, the gain of the compensation current is required to decrease so that compensation is performed on the frequency response.

It is to be noted that there are multiple manners to dispose the gain control unit 303, and the purpose is to control the voltages of the bases of the second transistor Q2, the third transistor Q3, the fourth transistor Q4, and the fifth transistor Q5 in a staggered compensation unit (including the first differential pair 301 and the second differential pair 302). The higher the controlled voltage, the easier it is for the transistor to turn on.

In this embodiment, the first adjustable current source I0, the second adjustable current source I1, the eighth transistor Q8, and the ninth transistor Q9 are disposed in the gain control unit 303 so that the voltages of the bases of the transistors in the staggered compensation unit connected to the gain control unit 303 can be controlled, thereby controlling the gains of the output currents of the staggered compensation unit and performing compensation for the frequency response. This arrangement has a simple circuit structure, is easy to implement, and is conducive to accurate adjustment of the gains of the currents.

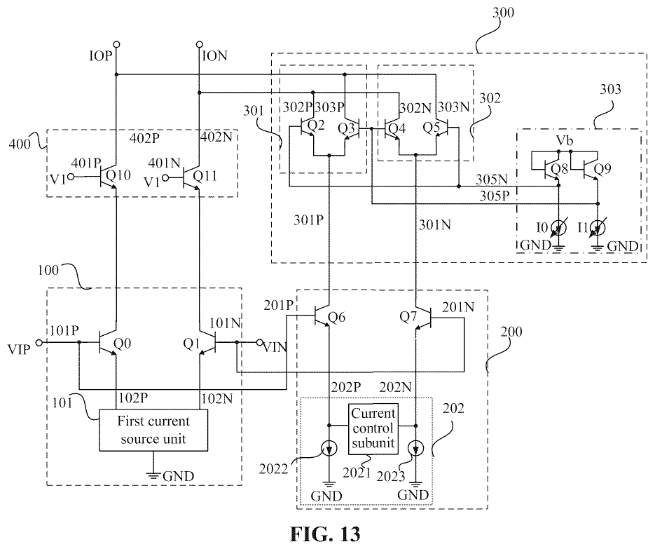

FIG. 13 is another diagram illustrating the circuit of an amplifier according to an embodiment of the present application. Referring to FIG. 13, the amplifier further includes a first current buffer module 400.

The first current buffer module 400 is connected in series between the transconductance amplification module 100 and the output terminal of the amplifier. The first current buffer module 400 includes a first buffer control terminal pair (including a terminal 401P and a terminal 401N), and the first buffer control terminal pair is connected to a reference voltage V1.

With continued reference to FIG. 13, the first current buffer module 400 includes a tenth transistor Q10 and an eleventh transistor Q11. A control terminal of the tenth transistor Q10 and a control terminal of the eleventh transistor Q11 are connected to the reference voltage V1. A first terminal of the tenth transistor Q10 and a first terminal of the eleventh transistor Q11 are connected to the output current pair of the transconductance amplification module 100. A second terminal of the tenth transistor Q10 and a second terminal of the eleventh transistor Q11 output a first buffer current pair (including a terminal 402P and a terminal 402N).

The first buffer current pair includes a positive-phase buffer current and a negative-phase buffer current. The positive-phase output current of the transconductance amplification module 100 is converted into the positive-phase buffer current through the tenth transistor Q10 and flows to a positive-phase output terminal. The negative-phase output current of the transconductance amplification module 100 is converted into the negative-phase buffer current through the eleventh transistor Q11 and flows to a negative-phase output terminal.

In this embodiment, the first current buffer module 400 is disposed so that the output current pair of the transconductance amplification module 100 can be buffered by using the transistors disposed in the first current buffer module 400, thereby improving the safety of the circuit.

It is to be noted that the transistor being the triode is used as an example for description in the preceding multiple embodiments, which does not limit the present application. In other embodiments, the transistor may also be disposed as a metal-oxide-semiconductor (MOS) tube.

An embodiment of the present application further provides an oscilloscope. The oscilloscope includes the amplifier provided in any one of the preceding embodiments. The oscilloscope provided in this embodiment has the beneficial effects of the amplifier provided in any one of the preceding embodiments, which is not repeated herein.

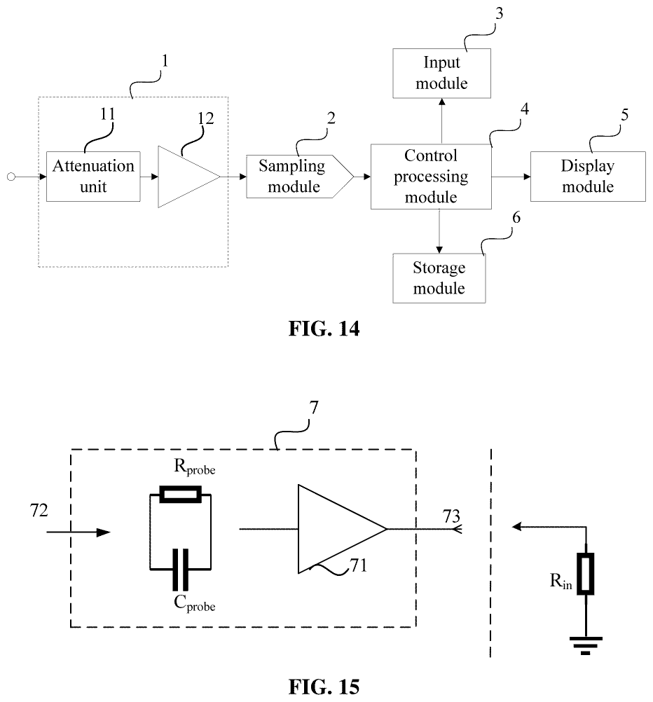

FIG. 14 is a diagram illustrating the structure of an oscilloscope according to an embodiment of the present application. Referring to FIG. 14, the oscilloscope includes a front-end module 1, a sampling module 2, an input module 3, a control processing module 4, a display module 5, and a storage module 6. The front-end module 1 includes an attenuation unit 11 and an amplifier 12. An input terminal of the amplifier 12 is connected to the attenuation unit 11.

FIG. 15 is another diagram illustrating the structure of an oscilloscope according to an embodiment of the present application. Referring to FIG. 15, the oscilloscope includes an oscilloscope probe 7 and an oscilloscope input resistor Rin.

An embodiment of the present application further provides an oscilloscope probe. The oscilloscope probe includes the amplifier provided in any one of the preceding embodiments. The oscilloscope probe provided in this embodiment has the beneficial effects of the amplifier provided in any one of the preceding embodiments, which is not repeated herein.

Referring to FIG. 15, the oscilloscope probe 7 includes a probe input terminal 72, a probe input resistor Rprobe, a probe input capacitor Cprobe, an amplifier 71, and a probe output terminal 73. An input terminal of the amplifier 71 is connected to the probe input resistor Rprobe and the probe input capacitor Cprobe separately. The probe output terminal 73 is connected to the oscilloscope input resistor Rin.

It is to be understood that various forms of the preceding flows may be used with steps reordered, added, or removed. For example, the steps described in the present application may be executed in parallel, in sequence, or in a different order as long as the desired results of the technical solutions provided in the present application are achieved. The execution sequence of these steps is not limited herein.

1. An amplifier, comprising:
a transconductance amplification module comprising an input control terminal pair, wherein the input control terminal pair is connected to an input signal pair, and the transconductance amplification module is configured to convert the input signal pair into an output current pair and output the output current pair;
a feedforward transconductance module comprising a first feedforward control terminal pair, wherein the first feedforward control terminal pair is connected to the input signal pair and outputs a feedforward current pair, and the feedforward current pair comprises a positive-phase feedforward current and a negative-phase feedforward current; and
a gain control module comprising a first differential pair and a second differential pair, wherein an input terminal of the first differential pair and an input terminal of the second differential pair serve as a feedforward current input terminal pair of the gain control module, the input terminal of the first differential pair is connected to the positive-phase feedforward current, a first output terminal of the first differential pair outputs a first positive-phase compensation current to compensate for a negative-phase output current of the output current pair, a second output terminal of the first differential pair outputs a second positive-phase compensation current to compensate for a positive-phase output current of the output current pair, the input terminal of the second differential pair is connected to the negative-phase feedforward current, a first output terminal of the second differential pair outputs a first negative-phase compensation current to compensate for the negative-phase output current of the output current pair, and a second output terminal of the second differential pair outputs a second negative-phase compensation current to compensate for the positive-phase output current of the output current pair.

2. The amplifier according to claim 1, wherein the transconductance amplification module comprises a first current source unit, a zeroth transistor, and a first transistor, the first current source unit comprises a first connection point pair, the first connection point pair comprises a first connection point and a second connection point, and the first current source unit is electrically connected to a first power supply voltage; and
a control terminal of the zeroth transistor and a control terminal of the first transistor serve as the input control terminal pair of the transconductance amplification module, a first terminal of the zeroth transistor is electrically connected to the first connection point of the first current source unit, a first terminal of the first transistor is electrically connected to the second connection point of the first current source unit, and a second terminal of the zeroth transistor and a second terminal of the first transistor output the output current pair of the transconductance amplification module.

3. The amplifier according to claim 2, wherein one of the following is satisfied:
the first current source unit comprises a first current source, a current input terminal of the first current source is electrically connected to the first connection point of the first current source unit and the second connection point of the first current source unit, and a current output terminal of the first current source is electrically connected to the first power supply voltage;
the first current source unit comprises a second current source, a first resistor unit, and a second resistor unit, the first resistor unit is connected in series between a current input terminal of the second current source and the first connection point of the first current source unit, the second resistor unit is connected in series between the current input terminal of the second current source and the second connection point of the first current source unit, and a current output terminal of the second current source is electrically connected to the first power supply voltage; or
the first current source unit comprises a third current source, a fourth current source, and a third resistor unit, a current input terminal of the third current source is electrically connected to the first connection point of the first current source unit, a current input terminal of the fourth current source is electrically connected to the second connection point of the first current source unit, the third resistor unit is further connected between the current input terminal of the third current source and the current input terminal of the fourth current source, and a current output terminal of the third current source and a current output terminal of the fourth current source are electrically connected to the first power supply voltage separately.

4. The amplifier according to claim 1, wherein the gain control module further comprises:
a gain control unit comprising a second connection point pair, wherein the second connection point pair of the gain control unit is electrically connected to a control terminal pair of the first differential pair and a control terminal pair of the second differential pair, the second connection point pair of the gain control unit outputs a second control current pair for gain control of the output currents of the first differential pair and the second differential pair.

5. The amplifier according to claim 4, wherein the first differential pair comprises a second transistor and a third transistor;
wherein a first terminal of the second transistor and a first terminal of the third transistor are electrically connected and serve as the input terminal of the first differential pair;
wherein a control terminal of the second transistor and a control terminal of a fifth transistor are electrically connected, the control terminal of the second transistor and a control terminal of the third transistor serve as the control terminal pair of the first differential pair;
wherein a second terminal of the second transistor serves as the first output terminal of the first differential pair and outputs the first positive-phase compensation current, and a second terminal of the third transistor serves as the second output terminal of the first

6. The amplifier according to claim 1, wherein the feedforward transconductance module further comprises a sixth transistor, a seventh transistor, and a second current source unit, the second current source unit comprises a third connection point pair;
wherein a control terminal of the sixth transistor and a control terminal of the seventh transistor serve as the first feedforward control terminal pair of the feedforward transconductance module, a first terminal of the sixth transistor and a first terminal of the seventh transistor are electrically connected to the third connection point pair of the second current source unit, a second terminal of the sixth transistor and a second terminal of the seventh transistor are electrically connected to the feedforward current input terminal pair of the gain control module separately; and
wherein the third connection point pair of the second current source unit outputs a first control current pair to perform frequency control on the output currents of the feedforward transconductance module.

7. The amplifier according to claim 6, wherein the third connection point pair of the second current source unit comprises a third connection point and a fourth connection point, the second current source unit further comprises:
a fifth current source, wherein a current input terminal of the fifth current source serves as the third connection point of the second current source unit, and a current output terminal of the fifth current source is electrically connected to a fifth power supply voltage;
a sixth current source, wherein a current input terminal of the sixth current source serves as the fourth connection point of the second current source unit, and a current output terminal of the sixth current source is electrically connected to a sixth power supply voltage; and
a current control subunit which is connected in series between the current input terminal of the fifth current source and the current input terminal of the sixth current source.

8. The amplifier according to claim 7, wherein one of the following is satisfied:
the current control subunit comprises a fourth resistor unit and a first capacitor unit, wherein a first terminal of the fourth resistor unit serves as a first terminal of the current control subunit, a second terminal of the fourth resistor unit is electrically connected to a first terminal of the first capacitor unit, and a second terminal of the first capacitor unit serves as a second terminal of the current control subunit;
the current control subunit comprises a second capacitor unit, wherein a first terminal of the second capacitor unit serves as a first terminal of the current control subunit, and a second terminal of the second capacitor unit serves as a second terminal of the current control subunit; or
the current control subunit comprises a fifth resistor unit, wherein a first terminal of the fifth resistor unit serves as a first terminal of the current control subunit, and a second terminal of the fifth resistor unit serves as a second terminal of the current control subunit.

9. The amplifier according to claim 4, wherein the gain control unit further comprises a first adjustable current source, a second adjustable current source, an eighth transistor, and a ninth transistor;
wherein a first terminal of the eighth transistor and a first terminal of the ninth transistor are electrically connected to a current input terminal of the first adjustable current source and a current input terminal of the second adjustable current source respectively, and a control terminal of the eighth transistor, a control terminal of the ninth transistor, a second terminal of the eighth transistor, and a second terminal of the ninth transistor are electrically connected to a second power supply voltage separately; and
wherein the current input terminal of the first adjustable current source and the current input terminal of the second adjustable current source serve as the second connection point pair of the gain control unit, a current output terminal of the first adjustable current source is electrically connected to a third power supply voltage, and a current output terminal of the second adjustable current source is electrically connected to a fourth power supply voltage.

10. The amplifier according to claim 1, further comprising a first current buffer module connected in series between the transconductance amplification module and an output terminal of the amplifier, wherein the first current buffer module comprises a first buffer control terminal pair, and the first buffer control terminal pair is connected to a reference voltage.

11. An oscilloscope, comprising a front-end module, a sampling module, an input module, a control processing module, a display module, and a storage module, wherein the front-end module comprises an attenuation unit and an amplifier, wherein an input terminal of the amplifier is connected to the attenuation unit;
and
wherein the amplifier comprises:
a transconductance amplification module comprising an input control terminal pair, wherein the input control terminal pair is connected to an input signal pair, and the transconductance amplification module is configured to convert the input signal pair into an output current pair and output the output current pair;
a feedforward transconductance module comprising a first feedforward control terminal pair, wherein the first feedforward control terminal pair is connected to the input signal pair and outputs a feedforward current pair, and the feedforward current pair comprises a positive-phase feedforward current and a negative-phase feedforward current; and
a gain control module comprising a first differential pair and a second differential pair, wherein an input terminal of the first differential pair and an input terminal of the second differential pair serve as a feedforward current input terminal pair of the gain control module, the input terminal of the first differential pair is connected to the positive-phase feedforward current, a first output terminal of the first differential pair outputs a first positive-phase compensation current to compensate for a negative-phase output current of the output current pair, a second output terminal of the first differential pair outputs a second positive-phase compensation current to compensate for a positive-phase output current of the output current pair, the input terminal of the second differential pair is connected to the negative-phase feedforward current, a first output terminal of the second differential pair outputs a first negative-phase compensation current to compensate for the negative-phase output current of the output current pair, and a second output terminal of the second differential pair outputs a second negative-phase compensation current to compensate for the positive-phase output current of the output current pair.

12. An oscilloscope probe, comprising a probe input terminal, a probe input resistor, a probe input capacitor, an amplifier, and a probe output terminal, wherein an input terminal of the amplifier is connected to the probe input resistor and the probe input capacitor separately; and
wherein the amplifier comprises:
a transconductance amplification module comprising an input control terminal pair, wherein the input control terminal pair is connected to an input signal pair, and the transconductance amplification module is configured to convert the input signal pair into an output current pair and output the output current pair;
a feedforward transconductance module comprising a first feedforward control terminal pair, wherein the first feedforward control terminal pair is connected to the input signal pair and outputs a feedforward current pair, and the feedforward current pair comprises a positive-phase feedforward current and a negative-phase feedforward current; and
a gain control module comprising a first differential pair and a second differential pair, wherein an input terminal of the first differential pair and an input terminal of the second differential pair serve as a feedforward current input terminal pair of the gain control module, the input terminal of the first differential pair is connected to the positive-phase feedforward current, a first output terminal of the first differential pair outputs a first positive-phase compensation current to compensate for a negative-phase output current of the output current pair, a second output terminal of the first differential pair outputs a second positive-phase compensation current to compensate for a positive-phase output current of the output current pair, the input terminal of the second differential pair is connected to the negative-phase feedforward current, a first output terminal of the second differential pair outputs a first negative-phase compensation current to compensate for the negative-phase output current of the output current pair, and a second output terminal of the second differential pair outputs a second negative-phase compensation current to compensate for the positive-phase output current of the output current pair.

13. The amplifier according to claim 4, wherein the second differential pair comprises a fourth transistor and a fifth transistor;
wherein a first terminal of the fourth transistor and a first terminal of the fifth transistor are electrically connected and serve as the input terminal of the second differential pair;
wherein a control terminal of the third transistor and a control terminal of the fourth transistor are electrically connected, and the control terminal of the fourth transistor and a control terminal of the fifth transistor serve as the control terminal pair of the second differential pair; and
wherein a second terminal of the fourth transistor serves as the first output terminal of the second differential pair and outputs the first negative-phase compensation current, and a second terminal of the fifth transistor serves as the second output terminal of the second differential pair and outputs the second negative-phase compensation current.

14. The amplifier according to claim 4, wherein the first differential pair comprises a second transistor and a third transistor, a first terminal of the second transistor and a first terminal of the third transistor are electrically connected and serve as the input terminal of the first differential pair, a control terminal of the second transistor and a control terminal of the third transistor are electrically connected and serve as the control terminal pair of the first differential pair, a second terminal of the second transistor serves as the first output terminal of the first differential pair and outputs the first positive-phase compensation current, and a second terminal of the third transistor serves as the second output terminal of the first differential pair and outputs the second positive-phase compensation current; and
wherein the second differential pair comprises a fourth transistor and the fifth transistor, a first terminal of the fourth transistor and a first terminal of the fifth transistor are electrically connected and serve as the input terminal of the second differential pair, a control terminal of the third transistor and a control terminal of the fourth transistor are electrically connected, the control terminal of the fourth transistor and a control terminal of the fifth transistor serve as the control terminal pair of the second differential pair, a second terminal of the fourth transistor serves as the first output terminal of the second differential pair and outputs the first negative-phase compensation current, and a second terminal of the fifth transistor serves as the second output terminal of the second differential pair and outputs the second negative-phase compensation current.

15. An oscilloscope, comprising the amplifier according to claim 2, wherein an input terminal of the amplifier serves as an input terminal of the oscilloscope.

16. An oscilloscope, comprising the amplifier according to claim 3, wherein an input terminal of the amplifier serves as an input terminal of the oscilloscope.

17. An oscilloscope, comprising the amplifier according to claim 4, wherein an input terminal of the amplifier serves as an input terminal of the oscilloscope.

18. An oscilloscope, comprising the amplifier according to claim 5, wherein an input terminal of the amplifier serves as an input terminal of the oscilloscope.

19. An oscilloscope, comprising the amplifier according to claim 13, wherein an input terminal of the amplifier serves as an input terminal of the oscilloscope.

20. An oscilloscope, comprising the amplifier according to claim 14, wherein an input terminal of the amplifier serves as an input terminal of the oscilloscope.
